(19) United States
(12) Patent Application Publication
(10) Pub. No.: US 2008/0089027 A1
(43) Pub. Date: Apr. 17, 2008

(54) Cooling Fan

(76) Inventor: Nai-Ko Ying, Taipei City (TW)

Correspondence Address: HDSL, 4331 STEVENS BATTLE LANE, FAIRFAX, VA, 22033, US

(21) Appl. No.: 11/549,680

(22) Filed: Oct. 16, 2006

(51) Int. Cl. H05K 7/20

(52) U.S. Cl. 361/695; 165/104.33; 454/184

(57) ABSTRACT

A cooling chip is arranged in front of a cooling fan, and a structure of which mainly includes a fan having a rectangular frame. A fan blade assembly, disposed in the interior of the frame, further includes a base formed as a hollow cylinder. Plural blades are arranged at the outer circumference of the base, and a front side face of which is arranged a cooling chip. The heat of the air in front of the fan is absorbed by the cooling chip, so the temperature of the air is lowered down. Cooperating with a forced airflow generated by the fan, the cooled air is blown forward, such that the need of the cooling function is satisfied.

### BACKGROUND OF THE INVENTION

1. Field of the Invention

The present invention relates to a fan device and, in particular, to a fan structure having a cooling chip.

2. Description of Prior Art

Due to express progress in modern technology, not only the size of an electronic product is reduced day by day, but also the operation speed of the electronic product is accelerated increasingly. Relatively, under the operation of a high speed, the heat generated in an electronic component also trends to extraordinarily high. In order to allow the electronic product operated normally under a working temperature, appropriate mechanism for heat dissipation therefore becomes a very important subject.

Particularly, in a computer host, it is comprised of different electronic components that are installed in an interior of a machine case, which belongs to an enclosed space. So, when a computer is running, a great amount of heat will be generated from the host. In order to avoid too much heat being accumulated inside the machine case, a fan is arranged together with the electronic components according to the prior arts. High temperature caused by the accumulation of heat may be prevented by means of the forced airflow generated by the fan to carry away the heat from the surrounding of the electronic components. Cooperating with the fan arranged on the machine case to draft out the hot air, the cooling down effect may be hopefully achieved.

However, the space in the interior of the machine case is so small that the forced airflow generated by the fan is restrained by the limited space. After several circulations, since the heat-dissipating effect completed by the airflow is very limited, so that, in order to enhance the heat-dissipation ability of the fan, according to the prior arts, at least one cooling chip is arranged on the fan. Through the operation of the cooling chip, which processes heat exchange with the surrounding air in a manner, such that the temperature of the surrounding air is lowered down. Furthermore, forced airflow generated by the fan will draft out the cold air to circulate around the machine case to process heat-dissipation function among the electronic components constituting the computer host.

However, in most cases, the cooling chip usually is arranged behind the fan, for facilitating the cold air generated by the cooling fan being blown forward by the forced airflow generated by the fan. But, the cooling operation of the cooling chip is sometimes so intensive that it is easy to make the fan occurred frosting phenomenon, which damps the fan or freezes the circuit. Therefore, the usage lives of the fan and the cooling chip are shortened or the operation of heat-dissipation executed by the fan is substantially influenced. In order to overcome these shortcomings, the present invention proposes a novel arrangement of a cooling fan, and a structure and an advantage of which are summarized as follow.

### SUMMARY OF THE INVENTION

With respect to above shortcomings, the main objective of the present invention is to provide a cooling fan, and a cooling chip of which is arranged in front of the fan. By arranging the cooling chip at the air exit in front of the fan, the cold air generated by the cooling effect of the cooling chip itself is blown farther away by the fan to serve the heat dissipation function. In the meantime, a forced airflow generated by the fan is continuously blown from inside to outside, such that the freezing phenomenon that is caused by the overcooling from the cooling chip and has influenced on the fan operation may be prevented.

In order to achieve the above objectives, the present invention provides a cooling fan, and a structure of which is mainly comprised of a fan having a rectangular frame. A fan blade assembly, disposed in the interior of the frame, further includes a base formed as a hollow cylinder. Plural blades are arranged at the outer circumference of the base, and a front side face of which is arranged a cooling chip. The heat of the air in front of the fan is absorbed by the cooling chip, so the temperature of the air is lowered down. Cooperating with a forced airflow generated by the fan, the cooled air is blown forward, such that the need of the cooling function is satisfied.

### BRIEF DESCRIPTION OF DRAWING

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 is a perspective view of the structure of one preferable embodiment according to the present invention;

FIG. 2 is a top view of the structure of one preferable embodiment according to the present invention;

FIG. 3 is a sectional view of the structure of one preferable embodiment according to the present invention;

FIG. 4 is a top view of the structure of another preferable embodiment according to the present invention; and

FIG. 5 is a sectional view of the structure of further preferable embodiment according to the present invention.

### DETAILED DESCRIPTION OF THE INVENTION

In cooperation with attached drawings, the technical contents and detailed description of the present invention will be as follows.

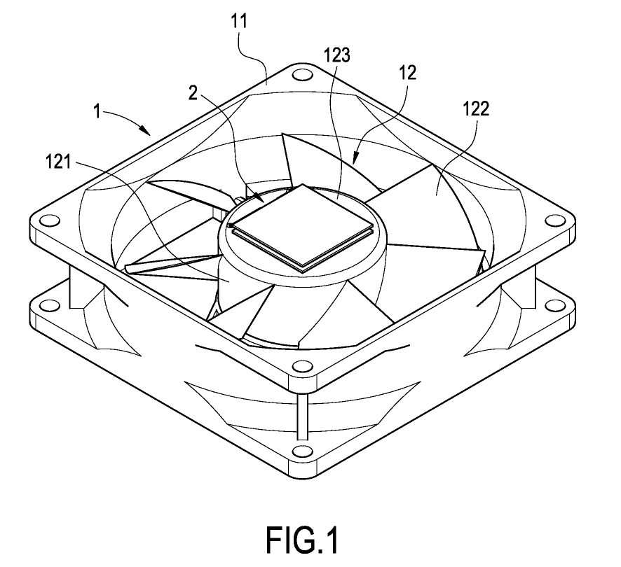

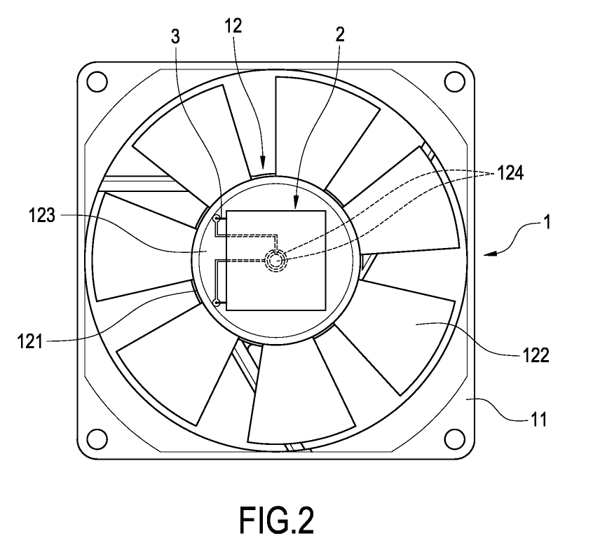

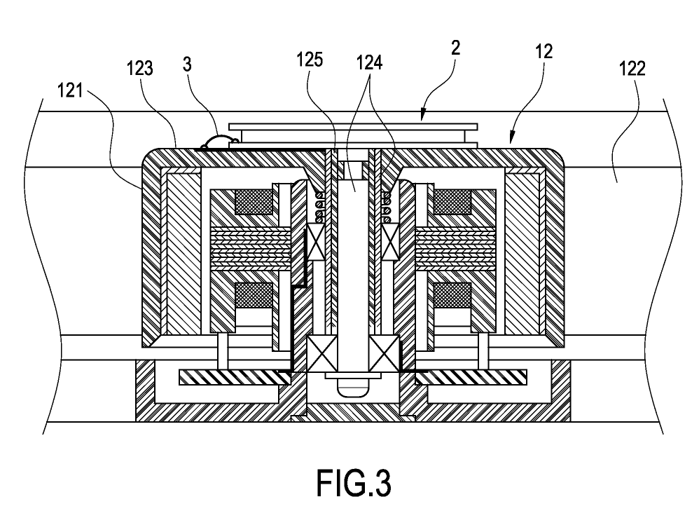

Please refer to FIG. 1 through FIG. 3, which are a perspective view, a top view, and a sectional view of one preferable embodiment according to the present invention. The fan structure according to the present invention is mainly comprised of a fan. In this embodiment, the fan 1 is an axial flow fan and further includes a rectangular frame 11, and in the interior of which a fan blade assembly 12 is arranged. The fan blade assembly 12 further includes a base 121 and plural blades 122, wherein the base 121 is formed as a hollow cylinder. Components used for rotating the fan blade assembly 12 are arranged in the base 121. These components are within the scope of prior arts, so detailed description is not presented herein. Plural blades 122 are arranged at the outer circumference of the base 121. Furthermore, at least one cooling chip 2 is arranged at the air-exiting side of the fan 1. In this embodiment, the cooling chip 2 is attached to the front side face 123 of the base 1. The cooling chip 2, a thermoelectric semiconductor, may absorb heat contained in the air to lower down the temperature thereof. In the meantime, the positive and negative electrode-conducting wire 3 connected with the cooling chip 2 is formed as the electric connection with an external power source via the printed circuit board (PCB) arranged on the base 121 and an electricity-conducting piece 124 arranged in the base 121. Furthermore, the electricity-conducting pieces 124 of the positive and negative electrodes are isolated by an insulating piece 125, as shown in the sectional view of FIG. 3.

Therefore, after above-said device is assembled and the cooling chip 2 starts to operate, the heat contained by the air surrounding the front air-exiting side of fan 1 is absorbed by the cooling chip 2 to lower down the temperature of the air to become with a cold condition. Cooperating with the forced airflow generated by the fan 1, the cold air formed at the front air-exiting side is brought along and is blown forward; therefore, the heat-dissipating effect is enhanced. In addition, because the cooling chip 2 now is disposed at the front position (i.e., the air-exiting side) of the fan 1, it is possible to send out the cold air continuously by the forced airflow generated by the fan without the occurrences of the freezing and frosting phenomena, otherwise the circuits of fan 1 and cooling chip 2 will be damped and their usage lives will be shortened.

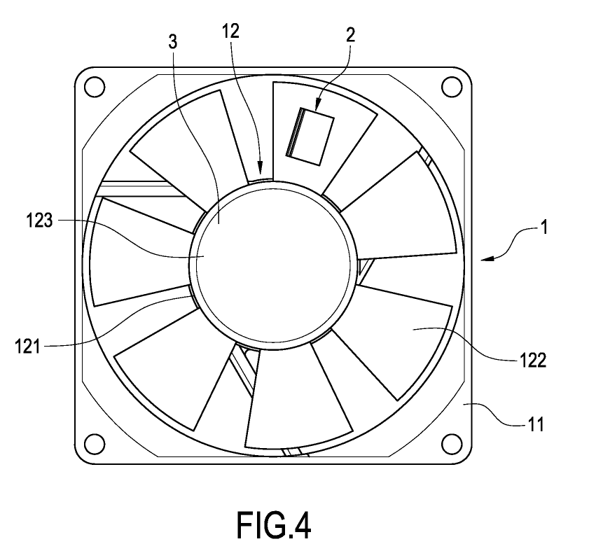

Please refer to FIG. 4, which shows a top view of the structure of another embodiment according to the present invention. In this case, besides the cooling chip 2 is arranged at the front side face 123 of the aforementioned base 121, it is also possible to arrange at least one cooling chip 2 at a front blade surface of the plural blades 122. In this embodiment, a cooling chip 2 is arranged with a single blade 122. In the meantime, the cooling chip 2 is electrically connected to the external power source via the electrode-conducting wires 3 and the electricity-conducting pieces 124 in the base 121. Therefore, when the fan 1 is operated to generate the forced airflow, the cold air formed by the action of the cooling chip 2 is blown forward in such a way to serve the heat-dissipating function. Furthermore, it is also possible to prevent the frosting phenomenon caused by the overcooling from the cooling chip 2 without generating any influence on the operation of fan 1.

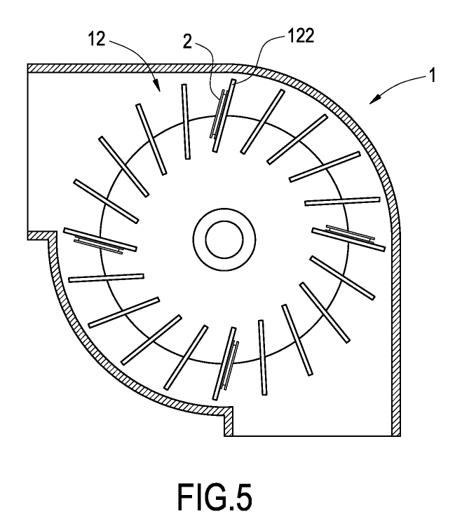

Except for an axial flow fan as shown in the structure of the aforementioned fan 1, the category of fan 1 may also be a blower as illustrated in FIG. 5. In this embodiment, at least one cooling chip 2 is arranged at the plural blades 122. In FIG. 5, there are four cooling chips 2 in total. When the fan 1 (i.e., the blower) is operated to generate the forced airflow, the cold air formed by the action of cooling chip 2 is blown forward so as to enhance the heat-dissipation effect that is already possessed. In the meantime, the forced airflow generated from the rotation of fan 1 continuously sweeps over the cooling chip 2, such that the frosting phenomena caused by the overcooling from cooling chip 2 may be prevented.

Aforementioned structures are only preferable embodiments according to the present invention, being not used to limit its executing scope. Any equivalent variation and modification made according to appended claims is all covered by the claims claimed by the present invention.

What is claimed is:

1. A cooling fan, a structure of which includes:
a fan having a fan blade assembly that further includes a base; and
at least a cooling chip, which is arranged on a front side face of the base;
wherein cold air caused by the cooling chip is blown forward by forced airflow generated by the fan, so the need of a heat-dissipating effect is achieved.

2. (canceled)

3. (canceled)

4. The cooling fan according to claim 1, wherein the cooling chip is electrically connected to an external power source via an electrode-conducting wire.

5. The cooling fan according to claim 1, wherein the fan is an axial flow type fan.

6. The cooling fan according to claim 1, wherein the fan is a blower.
